(19) United States
(12) Patent Application Publication
(10) Pub. No.: US 2006/0220183 A1
(43) Pub. Date: Oct. 5, 2006

(54) Semiconductor wafer having multiple semiconductor elements and method for dicing the same

(75) Inventors: Makoto Asai, Kariya-city (JP); Muneo Tamura, Nagoya-city (JP); Kazuhiko Sugiura, Nagoya-city (JP); Tetsuo Fujii, Toyohashi-city (JP)

Correspondence Address: POSZ LAW GROUP, PLC, 12040 SOUTH LAKES DRIVE, SUITE 101, RESTON, VA, 20191, US

(73) Assignee: DENSO CORPORATION, Kariya-city (JP)

(21) Appl. No.: 11/392,739

(22) Filed: Mar. 30, 2006

(30) Foreign Application Priority Data
Mar. 31, 2005 (JP) 2005-101554

(51) Int. Cl. H01L 29/06; H01L 21/00

(52) U.S. Cl. 257/622; 438/462

(57) ABSTRACT

A semiconductor wafer includes: a first layer having a first refraction index; a second layer having a second refraction index, which is different from the first refraction index; a plurality of semiconductor elements; and a layer removal region. The semiconductor elements are capable of being separated each other by irradiating a laser beam on the first layer along with a cutting line. The laser beam irradiation provides a modified region in the first layer so that the semiconductor elements are capable of being separated by a crack generated in the modified region. The layer removal region is provided such that the second layer in the layer removal region is removed from the wafer.

### CROSS-REFERENCE TO RELATED APPLICATION

This application is based on Japanese Patent Application No. 2005-101554 filed on Mar. 31, 2005, the disclosure of which is incorporated herein by reference.

### FIELD OF THE INVENTION

The present invention relates to a semiconductor wafer having multiple semiconductor elements and a method for dicing the same.

### BACKGROUND OF THE INVENTION

As shown in FIGS. 8A to 8C, a silicon wafer 100 includes a semiconductor integrated circuit or MEMS (i.e., micro electro mechanical systems) as a semiconductor element. Specifically, the wafer 100 includes multiple chips Dev. In a step of separating the wafer into each chip Dev, i.e., in a dicing step, the wafer 100 is cut by a dicing blade along with a cutting line DL so that the wafer is divided into multiple chips Dev. The dicing blade has a diamond abrasive grain embedded in the blade.

When the dicing blade is used in the dicing step, a cutting width is necessitated. Therefore, the number of chips to be separated from the wafer 100 is reduced by the cutting width. A manufacturing cost of each chip increases. Further, when the dicing blade cuts the wafer 100, water is used for preventing blade seizure caused by frictional heat. To protect the chip from the water, a protection device for protecting the chip is required. The protection device is, for example, a capping. Further, steps of the manufacturing process of the chip increase, and the number of maintenance steps for a dicing apparatus also increases.

Recently, the dicing step is performed by a laser beam. For example, a method for dicing a wafer by using a laser beam is disclosed in Japanese Patent No. 3408805. The laser beam prepared under a predetermined condition is irradiated on an object to be processed so that a modified region is formed. The object is cut along with the modified region.

Further, a wafer having multi-layer structure such as SOI (i.e., silicon on insulator) substrate and a SIMOX (i.e., separation by implanted oxygen) is developed. This multi-layer wafer is also divided into multiple chips by using a laser dicing method. However, it is difficult to form the modified region on the multi-layer wafer. In a case of a single layer wafer made of bulk silicon, the modified region is easily formed on the wafer by using multiple photon absorption effect caused by the laser beam irradiation. In a case of the multi-layer wafer, it is difficult to form the modified region uniformly. Here, the multiple photon absorption effect is such that multiple photons having the same properties or different properties are absorbed in a material. By using the multiple photon absorption effect, optical damage is generated on the material at a focal point and around the focal point. The optical damage induces thermal distortion. Thus, a crack is generated at a portion, at which the thermal distortion is occurred. Multiple cracks are formed so that the modified region, i.e., a modified layer, is provided by multiple cracks. Specifically, the modified region is a portion, in which the cracks are formed.

Here, for example, the wafer 100 includes a first silicon layer 101, a silicon oxide layer 102 and a second silicon layer 103, as shown in FIGS. 8B and 8C. In the wafer 100, each layer 101-103 has different optical properties. Specifically, refraction index of the laser beam in each layer 101-103 is different, since a thickness of each layer 101-103 and a material composing each layer 101-103 are different from each other. In FIGS. 8A to 8C, the refraction index of the second silicon layer 103 is different from the silicon oxide layer 102, and the refraction index of the silicon oxide layer 102 is different from the first silicon layer 101. Thus, at a boundary between the second silicon layer 103 and the silicon oxide layer 102, and at another boundary between the silicon oxide layer 102 and the first silicon layer 101, the laser beam L is reflected so that a reflected laser beam L1 is generated. Further, the laser beam L is scattered at the boundary so that a scattered laser beam L2 is generated. Here, CV represents a condenser lens. Thus, it is difficult to focus the laser beam L on a predetermined position or at a predetermined depth since the laser beam L is reflected and/or scattered intricately during the laser beam passes through the layers 101-103.

Accordingly, when the wafer 100 having the multi-layer structure is divided and separated by the laser beam, it is difficult to form a modified region modified by the laser beam on the wafer 100. Thus, yield ratio of the chip Dev as a product in the dicing step is reduced. Further, quality of the chip Dev may be reduced.

### SUMMARY OF THE INVENTION

In view of the above-described problem, it is an object of the present invention to provide a semiconductor wafer having multiple semiconductor elements with high yielding ratio and high quality. It is another object of the present invention to provide a method for dicing a semiconductor wafer having multiple semiconductor elements.

A semiconductor wafer includes: a first layer having a first refraction index; a second layer having a second refraction index, which is different from the first refraction index; a plurality of semiconductor elements disposed in the first and/or second layers; and a layer removal region. The first layer and the second layer are stacked in this order. The semiconductor elements are capable of being separated each other by irradiating a laser beam on the first layer along with a cutting line. The laser beam irradiation on the first layer provides a modified region in the first layer along with the cutting line so that the semiconductor elements are capable of being separated by a crack generated in the modified region. The layer removal region is provided in such a manner that the second layer in the layer removal region is removed from the wafer in order to irradiate the laser beam on the first layer in the layer removal region without passing through the second layer.

In the above wafer, the laser beam is irradiated on the first layer without passing through the second layer. Specifically, in the layer removal region, no second layer exists. Here, the second layer causes reflection and/or scattering of the laser beam when the laser beam is entered into the first layer from the second layer side. Thus, the laser beam is irradiated on the first layer without reflection and scattering so that the modified region is formed at a preliminarily designed region in the first layer. Accordingly, the wafer can be separated, i.e., deiced with accuracy. Specifically, each semiconductor element can be separated with high yielding ratio and high quality.

Further, a method for dicing a semiconductor wafer, which includes a first layer having a first refraction index, a second layer having a second refraction index, a plurality of semiconductor elements disposed in the first and/or second layers, and a layer removal region is provided. The first refraction index is different from the second refraction index, and the first layer and the second layer are stacked in this order. The method includes the steps of: removing a part of the second layer along with a cutting line so that the layer removal region is formed, wherein a laser beam is irradiated on the first layer in the layer removal region without passing through the second layer; irradiating the laser beam on the first layer along with the cutting line so that a modified region is formed in the first layer; and separating a semiconductor element from the wafer by using a crack generated by the modified region.

In the above method, the laser beam is irradiated on the first layer without passing through the second layer. Specifically, in the layer removal region, no second layer exists. Here, the second layer causes reflection and/or scattering of the laser beam when the laser beam is entered into the first layer from the second layer side. Thus, the laser beam is irradiated on the first layer without reflection and scattering so that the modified region is formed at a preliminarily designed region in the first layer. Accordingly, the wafer can be separated, i.e., deiced with accuracy. Specifically, each semiconductor element can be separated with high yielding ratio and high quality.

Further, a semiconductor wafer includes: a first layer having a first refraction index; a second layer having a second refraction index, which is different from the first refraction index; a top layer; a plurality of semiconductor elements disposed in the first layer, the second layer, and/or the top layer; and a layer removal region. The first layer, the second layer and the top layer are stacked in this order. The semiconductor elements are capable of being separated each other by irradiating a laser beam on the first layer along with a cutting line. The laser beam irradiation on the first layer provides a modified region in the first layer along with the cutting line so that the semiconductor elements are capable of being separated by a crack generated in the modified region. The layer removal region is provided in such a manner that the top layer in the layer removal region is removed from the wafer in order to irradiate the laser beam on the first layer in the layer removal region without passing through the top layer.

In the above wafer, the laser beam is irradiated on the first layer without passing through the top layer. Specifically, in the layer removal region, no top layer exists. Here, the top layer causes reflection and/or scattering of the laser beam when the laser beam is entered into the first layer from the second layer side. Thus, the laser beam is irradiated on the first layer without reflection and scattering so that the modified region is formed at a preliminarily designed region in the first layer. Accordingly, the wafer can be separated, i.e., deiced with accuracy. Specifically, each semiconductor element can be separated with high yielding ratio and high quality.

### BRIEF DESCRIPTION OF THE DRAWINGS

The above and other objects, features and advantages of the present invention will become more apparent from the following detailed description made with reference to the accompanying drawings. In the drawings:

FIG. 1 is a schematic plan view showing a semiconductor wafer according to a first embodiment of the present invention;

FIG. 2A is a cross sectional view showing the wafer taken along line IIA-IIA in FIG. 1, FIG. 2B is a cross sectional view showing the wafer taken along line IIB-IIB in FIG. 1, and FIGS. 2C and 2D are cross sectional views showing a semiconductor wafer according to a modification of the first embodiment of the present invention;

FIGS. 3A to 3C are cross sectional views showing a semiconductor wafer according to a second modification of the first embodiment of the present invention;

FIG. 4 is a schematic plan view showing a semiconductor wafer according to a second embodiment of the present invention;

FIG. 5A is a cross sectional view showing the wafer taken along line VA-VA in FIG. 4, FIG. 5B is a cross sectional view showing the wafer taken along line VB-VB in FIG. 4, and FIGS. 5C and 5D are cross sectional views showing a semiconductor wafer according to a modification of the second embodiment of the present invention;

FIG. 6 is a schematic plan view showing a semiconductor wafer according to a third embodiment of the present invention;

FIG. 7A is a cross sectional view showing the wafer taken along line VIIA-VIIA in FIG. 6, FIG. 7B is a cross sectional view showing the wafer taken along line VIIB-VIIB in FIG. 6, and FIGS. 7C and 7D are cross sectional views showing a semiconductor wafer according to a modification of the third embodiment of the present invention;

FIG. 8A is a schematic plan view showing a semiconductor wafer according to a prior art, FIG. 8B is a cross sectional view showing the wafer taken along line VIIIB-VIIIB in FIG. 8A, and FIG. 8C is a cross sectional view showing the wafer taken along line VIIIC-VIIIC in FIG. 8A;

FIGS. 9A and 9B are cross sectional views showing a semiconductor wafer according to a modification of the present invention; and

FIG. 10 is a cross sectional view showing a semiconductor wafer according to another modification of the present invention.

### DETAILED DESCRIPTION OF THE PREFERRED EMBODIMENTS

### First Embodiment

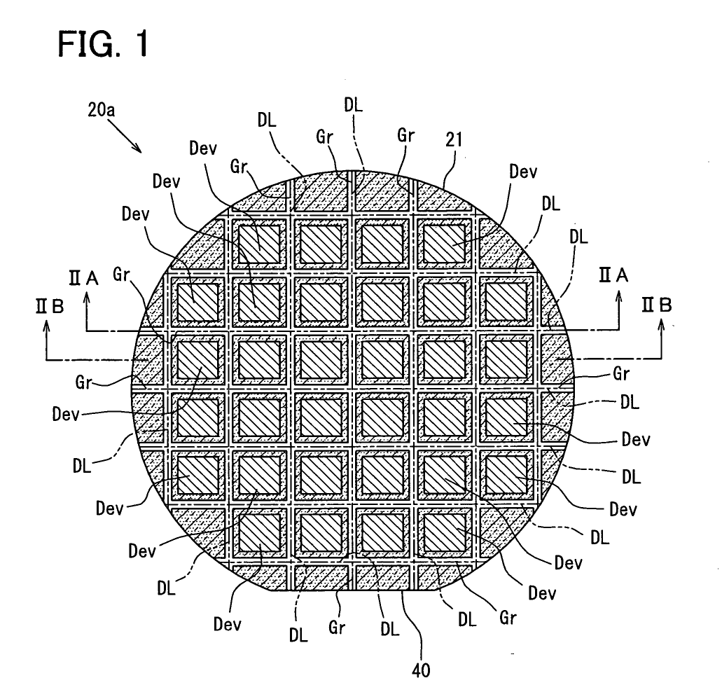

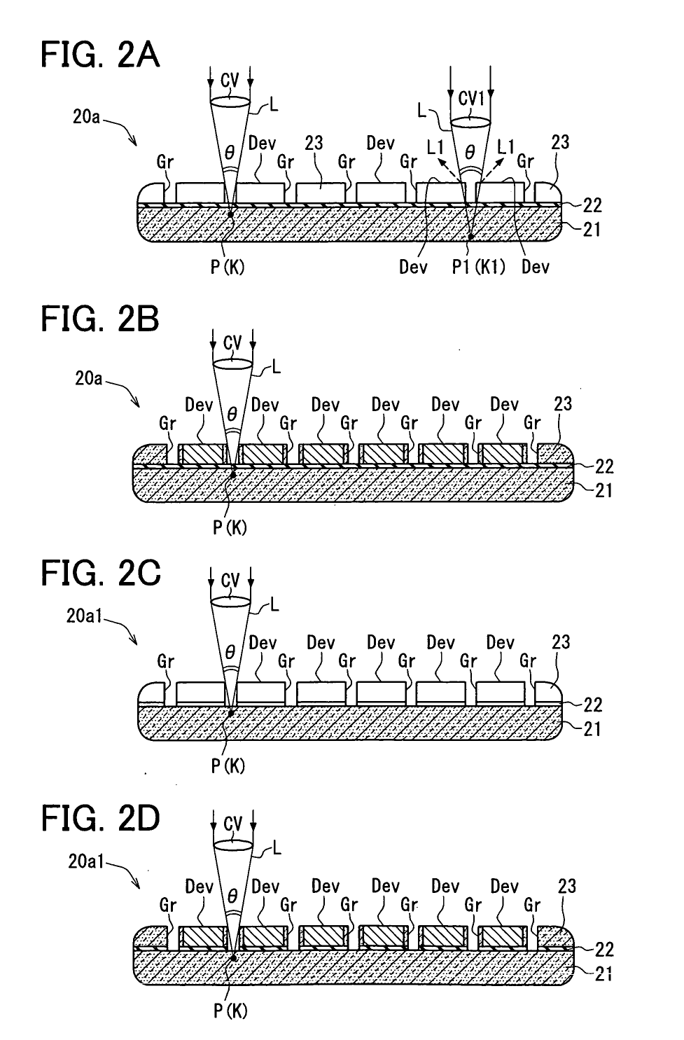

A semiconductor wafer 20a according to a first embodiment of the present invention is shown in FIG. 1. The wafer 20a is a silicon substrate 21 having a thin disk shape and made of silicon. The wafer 20a includes an orientation flat 40 for representing a crystal orientation. The orientation flat 40 of the wafer 20a is disposed on a part of an outer periphery of the wafer 20a. As shown in FIGS. 2A and 2B, the wafer 20a includes a silicon substrate 21, an embedded oxide layer 22 and a SOI layer 23, which are stacked in this order. Thus, the wafer 20a is a SOI wafer having multi-layer structure.

On the surface of the wafer 20a, multiple chips Dev are arranged to be a grid. Each chip Dev is formed on the wafer 20a in a semiconductor process such as a diffusion step. The wafer 20a is separated into the chips Dev by using a laser beam. The laser beam is scanned along with a cutting line DL, i.e., a dicing line.

A layer removal region as a groove Gr is formed on the wafer 20a along with the cutting line DL. Specifically, as shown in FIGS. 2A and 2B, the groove Gr is disposed on the cutting line DL, on which the laser beam L is irradiated. In the layer removal region, i.e., in the groove Gr, a part of the SOI layer 23 is removed from the silicon substrate 21. The modified region K is to be formed on and/or in the silicon substrate 21. Here, the part of the SOI layer 23 is disposed on an incident side of the laser beam L. The SOI layer 23 is removed by a layer removal step. Specifically, the SOI layer 23 is removed by, for example, a dry etching method or a wet etching method. The layer removal step is a preliminary step of a laser dicing step in a semiconductor device manufacturing process.

Thus, the laser beam L entering from the SOI layer side into the groove Gr is irradiated on the silicon substrate 21 through the embedded oxide layer 22 without passing through the SOI layer 23. Accordingly, the laser beam L is not reflected and scattered by the SOI layer 23. Thus, by removing the SOI layer 23, the laser beam L passes through the air around the wafer 20a, the oxide layer 22, and the silicon substrate 21. Here, the oxide layer 22 has small refraction index, and the silicon substrate 21 has large refraction index. On the other hand, when the wafer 20a includes the SOI layer 23 along with the cutting line DL, the laser beam L passes through the air, the SOI layer 23, the oxide layer 22, and the silicon substrate 21. Here, the SOI layer 23 has large refraction index. Thus, by removing the SOI layer 23, the reflection and the scattering of the laser beam L is suppressed. The reflection and the scattering of the laser beam L is generated at a boundary between two different mediums having largely different refraction indexes when the laser beam L passes through the boundary. Accordingly, the laser beam L can be focused on a predetermined position as a focal point P, which is disposed on a preliminarily designed point in the silicon substrate 21. Thus, the modified region K is formed precisely and uniformly, so that yielding ratio of the chip Dev and quality of the chip Dev are improved. Specifically, the modified region K is formed along with the cutting line appropriately, so that the wafer 20a can be separated and cut into multiple chips Dev along with the cutting line, i.e., with respect to the modified region K. After the chip Dev is separated from the wafer 20a in the dicing step, a mounting step, a bonding step, a sealing step and the like are performed so that the chip Dev provides, for example, a packaged IC or a LSI.

The SOI layer 23 to be removed from the wafer 20a in the layer removal step has a large refraction index compared with the oxide layer 22. Specifically, a difference of the refraction index between the SOI layer 23 and the oxide layer 22 is the largest difference. The oxide layer 22 has the comparatively small refraction index. Thus, the reflection of the laser beam L is effectively suppressed with removing only the part of the SOI layer 23 in the groove Gr so that the minimum number of the layers composing the wafer 20a is removed. Thus, the layer removal step for removing the SOI layer 23 is simplified. Further, the amount of waste liquid after a chemical process such as a dry etching process or a wet etching process can be reduced. Thus, burden and cost of maintenance of chemical process equipment is reduced.

FIGS. 2C and 2D show a semiconductor wafer 20a1 according to a modification of the first embodiment of the present invention. In the wafer 20a1, the oxide layer 22 together with the SOI layer 23 is removed from wafer 20a1 in the layer removal step. Here, the oxide layer 22 is stacked on the silicon substrate 21, and the difference of the refraction index between the oxide layer 22 and the silicon substrate 21 is large. Thus, the laser beam L is irradiated on the silicon substrate 21 directly without passing through the SOI layer 23 and the oxide layer 22. The reflection and/or the scattering of the laser beam L caused by the SOI layer 23 and the oxide layer 22 are not generated in the groove Gr. Specifically, in the wafer 20a1, by removing the SOI layer 23 and the oxide layer 22, the laser beam L passes through the air and the silicon substrate 21. On the other hand, when the wafer 20a includes the SOI layer 23 and the oxide layer 22, the laser beam L passes through the air, the SOI layer 23, the oxide layer 22, and the silicon substrate 21. Thus, by removing the SOI layer 23 and the oxide layer 22, the reflection and the scattering of the laser beam L is suppressed. The reflection and the scattering of the laser beam L is generated at a boundary between two different mediums having largely different refraction indexes when the laser beam L passes through the boundary. Accordingly, the laser beam L can be focused on a predetermined position as a focal point P, which is disposed on a preliminarily designed point in the silicon substrate 21. Thus, the modified region K is formed precisely and uniformly, so that yielding ratio of the chip Dev and quality of the chip Dev are improved.

Further, as shown in FIG. 1, the groove Gr is disposed on a whole area including all cutting lines DL, on which the laser beam L is irradiated. Specifically, the groove Gr is disposed between one periphery end of the wafer 20a to the other periphery end. The groove Gr is parallel to or perpendicular to a certain crystal orientation of the wafer 20a. Thus, in all area, on which the laser beam L is irradiated, the modified region K is formed precisely and uniformly. It is not necessary to control start and stop of irradiation of the laser beam L much precisely, so that an irradiation control means of the laser beam L is simplified.

Further, as shown in FIGS. 2A and 2B, an aperture angle θ of the laser beam L is controlled by the condenser lens CV so that the laser beam L is entered into the groove Gr within a width of the groove Gr. However, the condenser lens CV may be displaced in order to focus the laser beam L on another focal point P1, which is disposed on a deeper side of the silicon substrate 21. Specifically, the other focal point P1 is closer to the backside of the wafer 20a than the focal point P. Here, on the backside of the wafer 20a, there is no chip. In this case the condenser lens CV1 is disposed closer to the wafer 20a shown as CV1 in FIG. 1A. A part of the laser beam L may be reflected on an edge (i.e., a corner) of the chip Dev, which is disposed on both sides of the groove Gr. However, even in this case, the above described effects are obtained, so that the modified region K1 is formed precisely and uniformly. The yielding ratio of the chip Dev and quality of the chip Dev are improved.

Thus, when the laser beam L is irradiated on the silicon substrate 21 directly without passing through the SOI layer 23 and the oxide layer 22, as shown in FIGS. 2A and 2B, or when the laser beam L is irradiated on the silicon substrate 21 through the oxide layer 22 without passing through the SOI layer 23, as shown in FIGS. 2C and 2D, the modified region K, K1 can be formed on and/or in the silicon substrate 21 at a predetermined position precisely and uniformly. Thus, the wafer 20a, 20a1 is cut (i.e., diced) and separated appropriately, so that the yielding ratio and the quality of the chip Dev are improved.

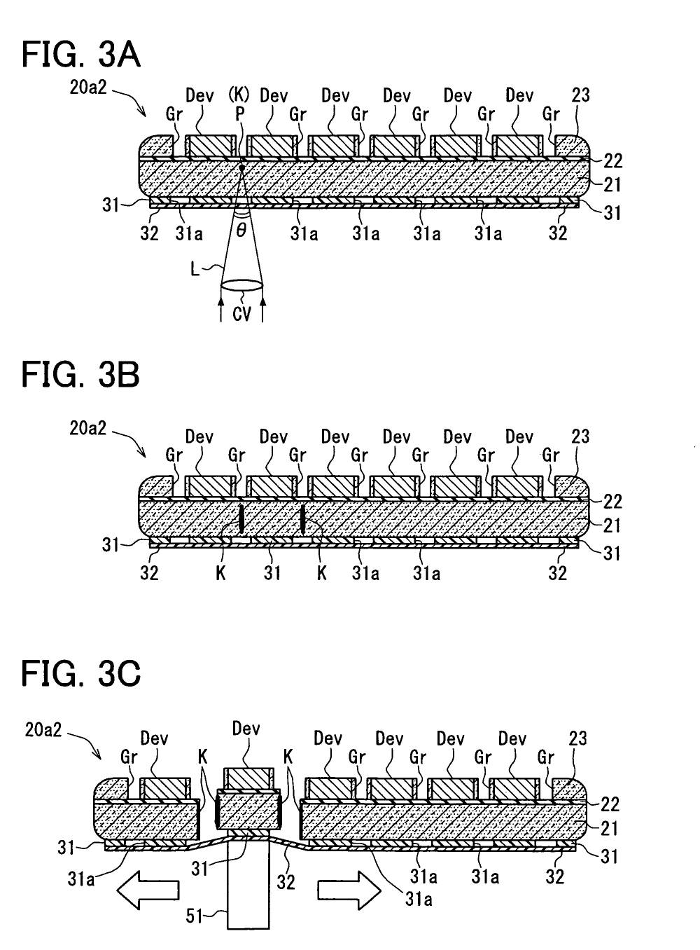

Next, a semiconductor wafer 20a2 according to a second modification of the first embodiment of the present invention is shown in FIGS. 3A to 3C. In the wafer 20a2, a die-attach film (i.e., a die-bond film, or DAF) 31 is applied on the backside of the wafer 20a2. The die-attach film prevents the chip Dev from being dispersed just after the dicing step. Further, a dicing film (i.e., a dicing sheet or a dicing tape) 32 is applied on the DAF 31.

The DAF 31 includes multiple parts, which are disposed on multiple positions of the backside of the silicon substrate 21 corresponding to the chips Dev, respectively. These multiple parts of the DAF 31 are bundled by one dicing film 32 so that the dicing film 32 together with each part of the DAF 31 is applied on the wafer 20a2. The DAF 31 and the dicing film 32 are formed in such a manner that a synthetic resin film is bonded to the wafer 20a2 with an adhesive. The DAF 31 includes a clearance 31a, which functions as a layer removal region similar to the groove Gr. Specifically, the clearance 31a corresponds to the groove Gr. Therefore, by irradiating the laser beam L on the silicon substrate 21 from the backside of the wafer 20a2 through the clearance 31a, a modified region K is formed in the silicon substrate 21. The laser beam L is directly irradiated on the silicon substrate 21 without passing through the DAF 31. Thus, by removing a part of the DAF 31 and by forming the clearance 31a, the reflection and the scattering of the laser beam L caused by the DAF 31 are suppressed, i.e., prevented.

As shown in FIG. 3B, when the modified region K is sufficiently formed by the laser beam L, the modified region K along with the cutting line DL is formed to be a slit shape in the thickness direction of the silicon substrate 21. Accordingly, as shown in FIG. 3C, in an expanding step, the wafer 20a2 is pulled from both sides of the wafer 20a2 toward an outer radial direction, which is shown as an arrow in FIG. 3C. Further, the wafer 20a2 is pushed up from the backside of the wafer 20a2 with a pushing-up member 51. The force of pushing up the wafer 20a2 caused by the pushing-up member 51 transmits the surface of the wafer 20a2, so that a crack is generated from the modified region K as a starting point. Thus, the chip Dev is separated from the wafer 20a2 by the crack. Although, in FIG. 3C, only one chip Dev is pushed up by the pushing-up member 51, a whole backside of the wafer 20a2 may be pushed up by the pushing-up member 51 in the expanding step so that the wafer 20a2 is uniformly pushed up. In this case, multiple chips Dev are separated at one time.

In the wafers 20a, 20a1, 20a2 according to the first embodiment, the groove Gr and/or the clearance 31a provide a layer removal region having a grid shape. The layer removal region is disposed along with the cutting line DL, and disposed from one outer periphery end of the wafer 20a, 20a1, 20a2 to the other outer periphery end so that the layer removal region reaches the outer periphery of the wafer 20a, 20a1, 20a2. By forming the layer removal region, only the SOI layer 23 or both of the SOI layer and the oxide layer 22 is removed from the wafer 20a, 20a1, 20a2 at a position of the layer removal region. Thus, the pushing-up force applied to the wafer 20a, 20a1, 20a2 by the pushing-up member 51 is transmitted to the whole backside surface of the wafer 20a, 20a1, 20a2 without being limited by an outer periphery region R, which is later described. Further, the layer removal region can be formed at a predetermined portion of the wafer 20a, 20a1, 20a2, so that the chip Dev is uniformly and precisely separated by a laser dicing method without occurring a pitching and/or a cutting deviation.

Here, the chip Dev represents a semiconductor element, and the silicon substrate 21, the oxide layer 22 and the SOI layer 23 are one example. The silicon substrate 21, the oxide layer 22 and the SOI layer 23 represent multiple layers having different refraction indexes. The silicon substrate 21 represents a modified region forming layer, and the oxide layer 22 and the SOI layer 23 represent other layers other than the modified region forming layer.

### Second Embodiment

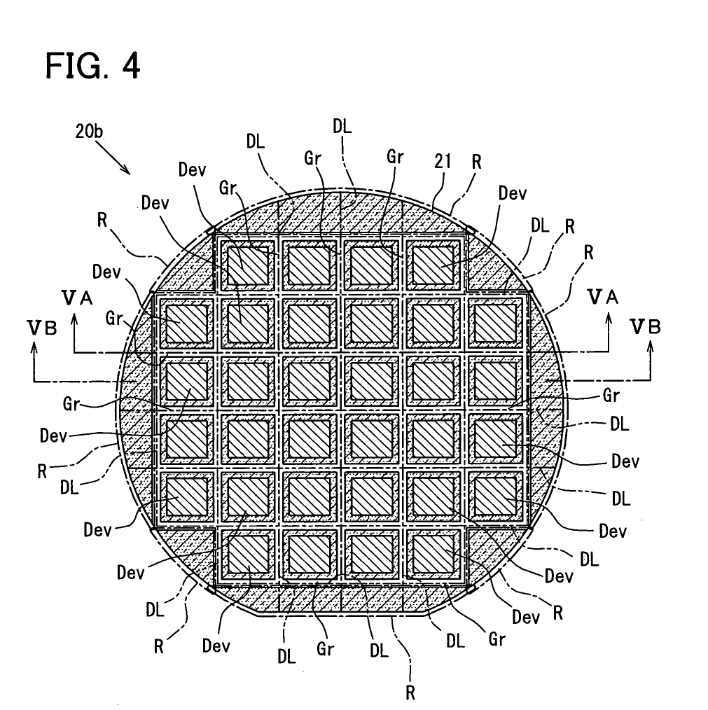

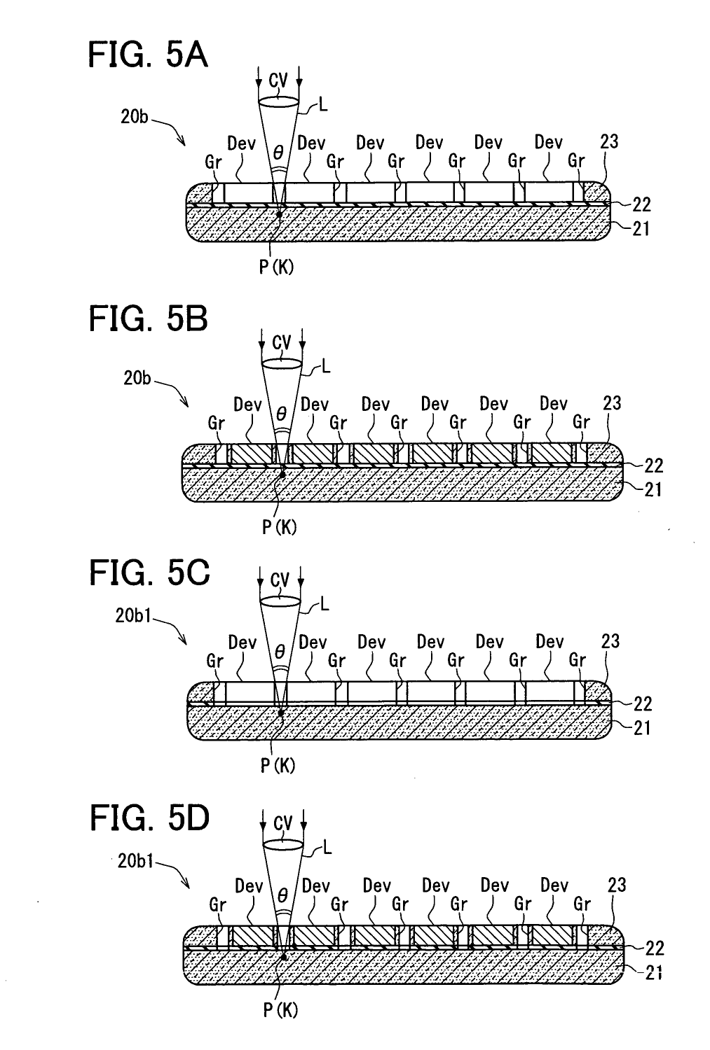

A semiconductor wafer 20b according to a second embodiment of the present invention is shown in FIGS. 4, 5A and 5B. In the wafer 20b, the layer removal region, i.e., the groove Gr, is formed around the chip Dev. Therefore, the groove Gr does not reach the outer periphery of the wafer 20b. The groove Gr in the wafer 20b is not formed in an outer periphery region R, so that the groove does not disposed from one outer periphery end of the wafer 20b to the other outer periphery end.

As shown in FIG. 4, the groove Gr along with the cutting line DL is formed in such a manner that the groove Gr surrounds multiple chips Dev in the wafer 20b. Specifically, the groove Gr surrounds a chip to be formed region. Thus, the groove Gr in the wafer 20b is formed to minimize an area of the groove Gr on the cutting line DL of the laser beam L. The groove Gr is formed in a necessity minimum area for separating all chips Dev. In the groove Gr, only part of the SOI layer 23 is removed from the wafer 20b, so that the oxide layer 22 and the silicon substrate 21 remains in the wafer 20b. Thus, a part of the SOI layer 23 to be removed from the wafer 20b is minimized. Specifically, the necessity minimum part of the SOI layer 23 is removed from the wafer 20b. Thus, the reflection and the scattering of the laser beam L are limited, i.e., suppressed. Accordingly, the layer removal step for removing the part of the SOI layer 23 is simplified. Further, the amount of waste liquid after a chemical process such as a dry etching process or a wet etching process can be reduced. Thus, burden and cost of maintenance of chemical process equipment is reduced.

FIGS. 5C and 5D show a semiconductor wafer 20b1 according to a modification of the second embodiment of the present invention. In the wafer 20b1, the oxide layer 22 together with the SOI layer 23 is removed from wafer 20b1 in the layer removal step. Here, the oxide layer 22 is stacked on the silicon substrate 21, and the difference of the refraction index between the oxide layer 22 and the silicon substrate 21 is large. Thus, the laser beam L is irradiated on the silicon substrate 21 directly without passing through the SOI layer 23 and the oxide layer 22. The reflection and/or the scattering of the laser beam L caused by the SOI layer 23 and the oxide layer 22 are not generated in the groove Gr. Specifically, in the wafer 20b1, by removing the SOI layer 23 and the oxide layer 22, the laser beam L passes through the air and the silicon substrate 21. Thus, by removing the SOI layer 23 and the oxide layer 22, the reflection and the scattering of the laser beam L is suppressed. Accordingly, the laser beam L can be focused on a predetermined position as a focal point P, which is disposed on a preliminarily designed point in the silicon substrate 21. Thus, the modified region K is formed precisely and uniformly, so that yielding ratio of the chip Dev and quality of the chip Dev are improved. Further, the layer removal step for removing the SOI layer 23 and the oxide layer 22 is simplified since the groove Gr in the wafer 20b1 is formed in the necessity minimum area in the wafer 20b1 along with the cutting line DL of the laser beam L. Thus, the wafer 20b1 has the advantages of the wafer 20b and the wafer 20a1, i.e., the advantages of simple layer removal step and direct irradiation on the silicon substrate 21.

Here, the cutting line DL represents a laser irradiation portion, and the groove Gr is disposed in the necessity minimum area for separating all chips from the wafer 20b.

### Third Embodiment

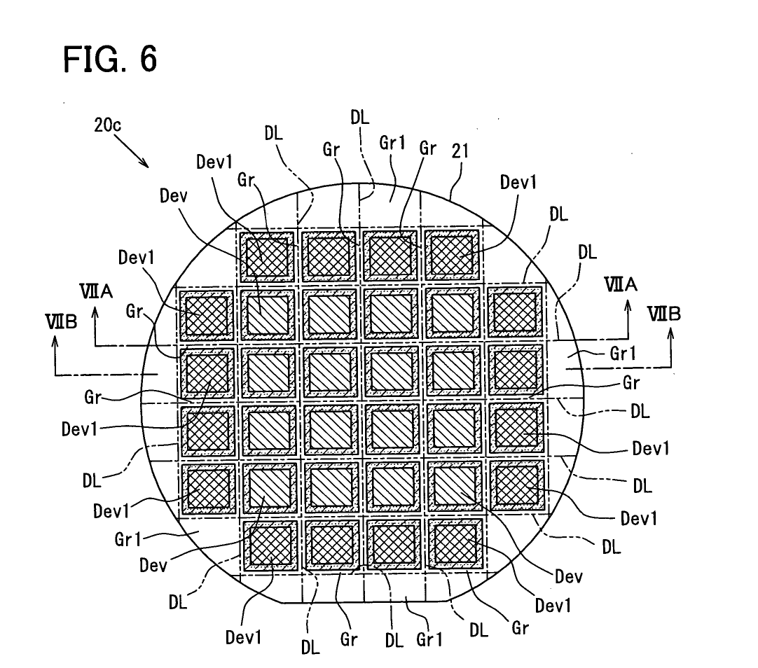

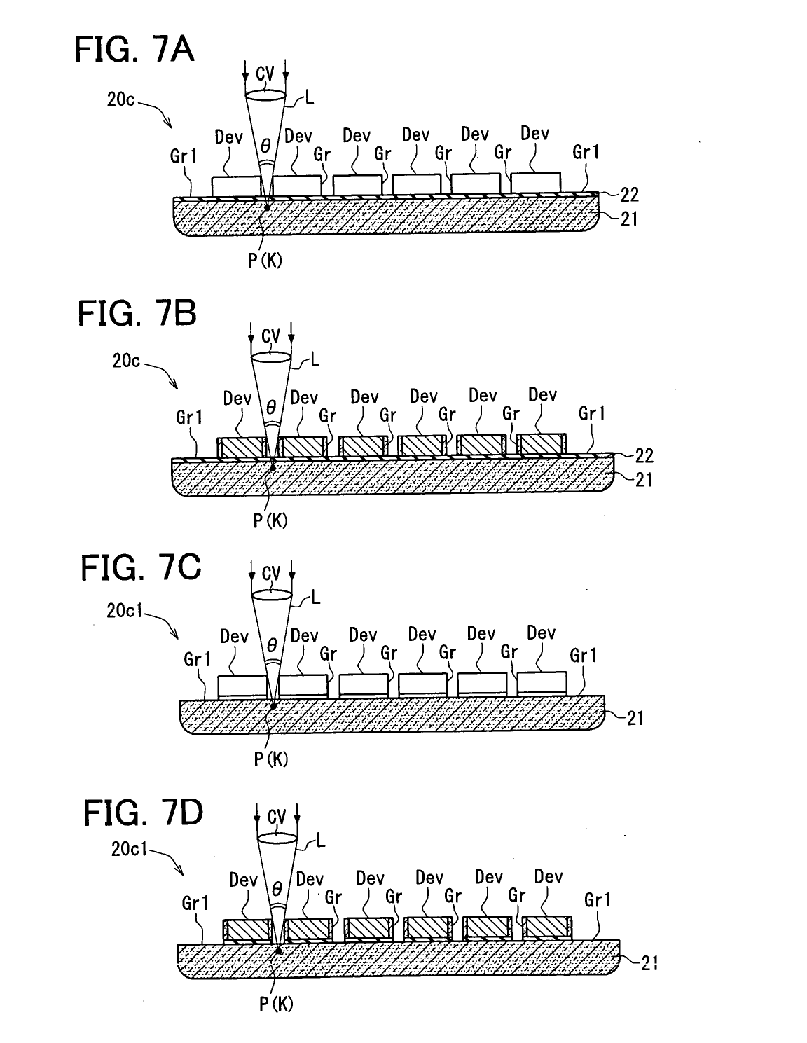

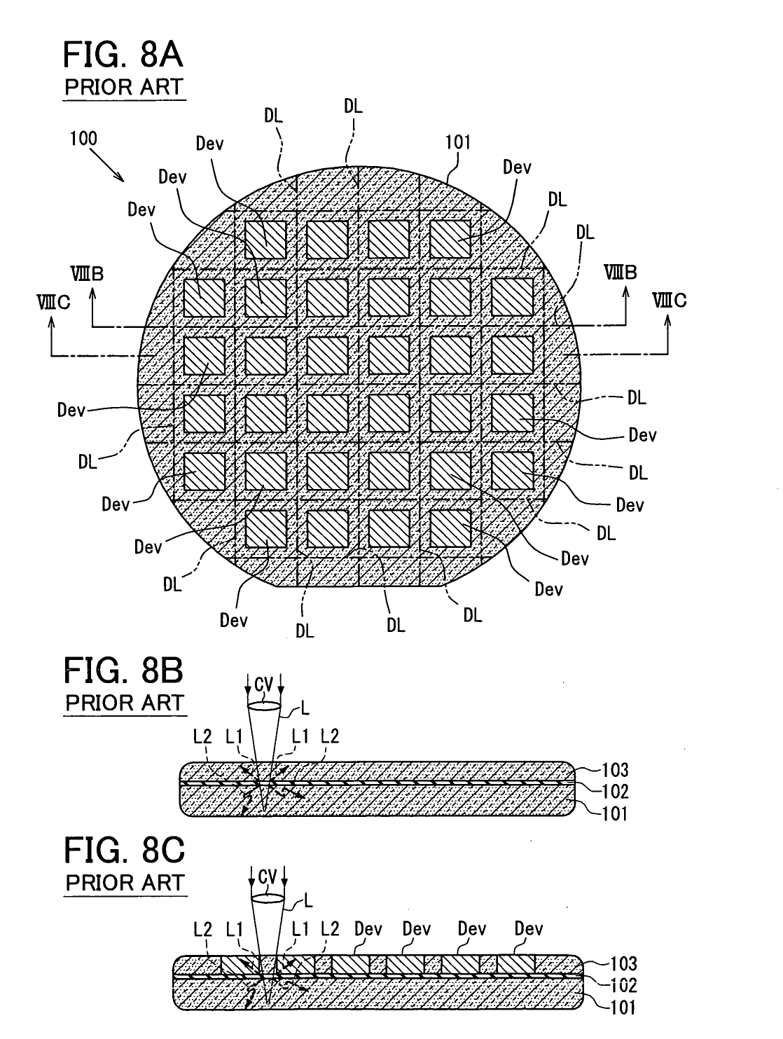

A semiconductor wafer 20c according to a third embodiment of the present invention is shown in FIGS. 6, 7A and 7B. In the wafer 20c, an outer layer removal region Gr1 disposed in the outer periphery region R is formed. Specifically, the outer layer removal region Gr1 is disposed on an outside from the utmost outer chip Dev1. Here, the outer periphery region R is disposed outside of the utmost outer chip Dev1, which is disposed on the utmost outside of the wafer 20c. The outer layer removal region Gr1 is formed on a wide area including the cutting line DL. Thus, not only the groove Gr as the layer removal region but also the outer layer removal region Gr1 are formed in the wafer 20c so that the groove Gr and the outer layer removal region Gr1 are disposed on the wafer 20c other than the chips Dev and its surrounding area. Here, in the wafer 20c, only a part of the SOI layer 23 is removed from the wafer 20c, and the oxide layer 22 and the silicon substrate 21 are not removed from the wafer 20c.

By forming the groove Gr between the chips Dev and the outer layer removal region Gr1 in the outer periphery region R, the part of the SOI layer 23, which is an unnecessary portion for the chip Dev, is removed from the wafer 20c. In this case, the pushing-up force applied to the wafer 20c by the pushing-up member 51 from the backside of the wafer 20c is transmitted to the whole backside surface of the wafer 20c. Further, the SOI layer 23 is not disposed on the wafer 20c other than the chip Dev and its surrounding portion. The modified region K is formed in the silicon substrate 21 precisely and uniformly so that the chip Dev is uniformly and precisely separated by a laser dicing method without occurring a pitching and/or a cutting deviation.

FIGS. 7C and 7D show a semiconductor wafer 20c1 according to a modification of the third embodiment of the present invention. In the wafer 20c1, the oxide layer 22 together with the SOI layer 23 is removed from wafer 20c1 in the layer removal step. Thus, the laser beam L is irradiated on the silicon substrate 21 directly without passing through the SOI layer 23 and the oxide layer 22. The reflection and/or the scattering of the laser beam L caused by the SOI layer 23 and the oxide layer 22 are not generated in the groove Gr and the outer layer removal region Gr1. Thus, by removing the SOI layer 23 and the oxide layer 22, the reflection and the scattering of the laser beam L is suppressed. Accordingly, the laser beam L can be focused on a predetermined position as a focal point P, which is disposed on a preliminarily designed point in the silicon substrate 21. Thus, the modified region K is formed precisely and uniformly, so that yielding ratio of the chip Dev and quality of the chip Dev are improved. Thus, the wafer 20c1 has the advantages of the wafer 20b and the wafer 20a1, i.e., the advantages of uniform separation of the chip Dev and direct irradiation on the silicon substrate 21.

(Modifications)

Although the wafer 20a, 20a1, 20a2, 20b, 20b1, 20c, 20c1 is made of silicon, the wafer 20a, 20a1, 20a2, 20b, 20b1, 20c, 20c1 may be made of other semiconductor material such as gallium arsenide.

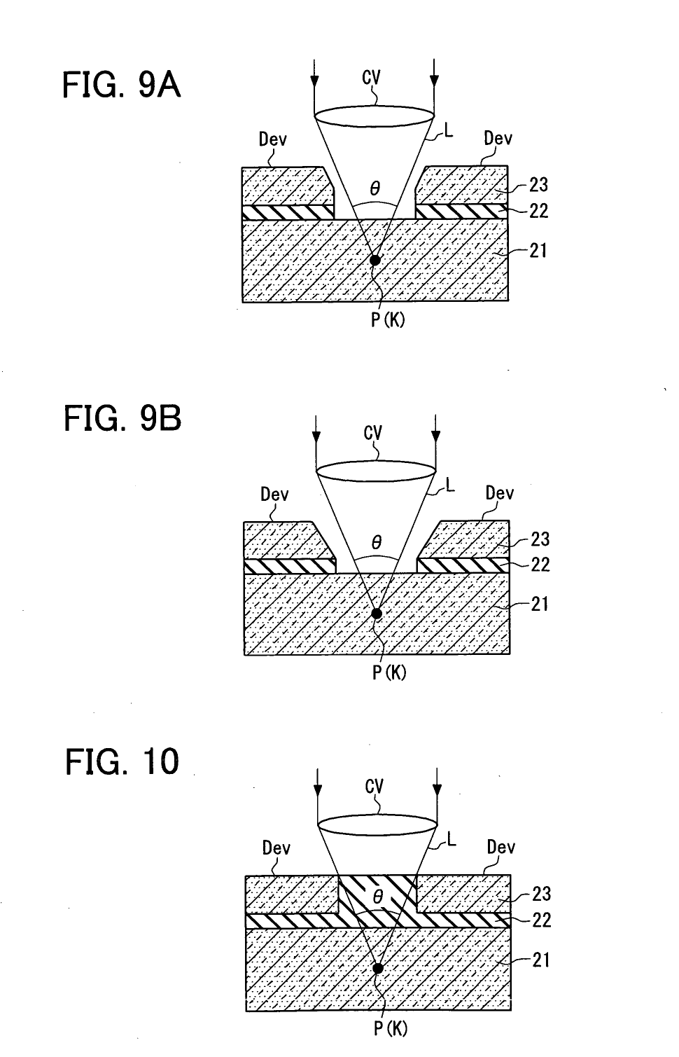

Although a part of the laser beam L may be reflected on an edge (i.e., a corner) of the chip Dev, which is disposed on both sides of the groove Gr, when the condenser lens CV1 is disposed closer to the wafer 20a shown as CV1 in FIG. 1A, the wafer 20a, 20a1, 20a2, 20b, 20b1, 20c, 20c1 may have a groove with a tapered edge, as shown in FIGS. 9A and 9B. In this case, a part of the edge of the chip Dev is removed from the chip Dev so that the edge has a tapered shape. The laser beam L is easily irradiated on the silicon substrate 21 without being reflected by the edge of the chip Dev. Thus, the laser beam L is effectively entered into the groove Gr, so that the modified region K is easily formed.

Further, the groove Gr may be filled with a member made of the same material as the oxide layer 22, as shown in FIG. 10. In this case, the laser beam L entering from the SOI layer side is irradiated on the silicon substrate 21 through the embedded oxide layer 22 without passing through the SOI layer 23. Accordingly, the laser beam L is not reflected and scattered by the SOI layer 23. Thus, the laser beam L passes through the air around the wafer 20a, the oxide layer 22, and the silicon substrate 21. Thus, by removing the SOI layer 23 and by filling the groove with the member made of the same material as the oxide layer 22, the reflection and the scattering of the laser beam L is suppressed. Accordingly, the laser beam L can be focused on a predetermined position as a focal point P, which is disposed on a preliminarily designed point in the silicon substrate 21. Thus, the modified region K is formed precisely and uniformly, so that yielding ratio of the chip Dev and quality of the chip Dev are improved.

The present invention has the following aspects.

A semiconductor wafer includes: a first layer having a first refraction index; a second layer having a second refraction index, which is different from the first refraction index; a plurality of semiconductor elements disposed in the first and/or second layers; and a layer removal region. The first layer and the second layer are stacked in this order. The semiconductor elements are capable of being separated each other by irradiating a laser beam on the first layer along with a cutting line. The laser beam irradiation on the first layer provides a modified region in the first layer along with the cutting line so that the semiconductor elements are capable of being separated by a crack generated in the modified region. The layer removal region is provided in such a manner that the second layer in the layer removal region is removed from the wafer in order to irradiate the laser beam on the first layer in the layer removal region without passing through the second layer.

In the above wafer, the laser beam is irradiated on the first layer without passing through the second layer. Specifically, in the layer removal region, no second layer exists. Here, the second layer causes reflection and/or scattering of the laser beam when the laser beam is entered into the first layer from the second layer side. Thus, the laser beam is irradiated on the first layer without reflection and scattering so that the modified region is formed at a preliminarily designed region in the first layer. Accordingly, the wafer can be separated, i.e., deiced with accuracy. Specifically, each semiconductor element can be separated with high yielding ratio and high quality.

Alternatively, a difference between the first refraction index of the first layer and the second refraction index of the second layer, the first and the second layers which are adjacent each other, may be the largest difference of a refraction index in the wafer. In this case, the second layer as a factor of the laser beam reflection and scattering is eliminated. Since the difference of refraction index between the first layer and the second layer in the wafer is the largest difference, the laser beam is refracted at a boundary between the first layer and the second layer. By removing only the second layer, the reflection and the scattering of the laser beam are effectively suppressed. Accordingly, the layer removal step is simplified.

Alternatively, the layer removal region may include a whole area of the laser beam irradiation portion on the first layer. In this case, the laser beam irradiation control is simplified.

Alternatively, the layer removal region may be disposed in a necessity minimum area for separating all semiconductor elements. In this case, only by removing a minimum part of the second layer from the wafer, the reflection and scattering of the laser beam is effectively suppressed. Thus, the layer removal step is simplified.

Alternatively, the layer removal region may be a groove so that the second layer is divided by the groove, and the second layer facing the groove may have a corner, which is tapered toward the first layer.

Alternatively, the first layer may include a silicon substrate, and the second layer may include a SOI layer and an oxide layer.

Alternatively, the wafer further includes: a die-attach film having a plurality of film parts; and a dicing film. The layer removal region is a groove so that the second layer is divided by the groove. The die-attach film is disposed on a backside of the first layer, which is opposite to the second layer, so that each film part of the die-attach film contacts the backside of the first layer. The dicing film is disposed on the die-attach film so that the film parts of the die-attach film are bundled by the dicing film. The die-attach film further includes a clearance between two neighboring film parts of the die-attach film. The clearance corresponds to the groove. The laser beam is capable of irradiating on the first layer from the backside of the first layer through the clearance so that the modified region is formed in the first layer.

Further, a method for dicing a semiconductor wafer, which includes a first layer having a first refraction index, a second layer having a second refraction index, a plurality of semiconductor elements disposed in the first and/or second layers, and a layer removal region is provided. The first refraction index is different from the second refraction index, and the first layer and the second layer are stacked in this order. The method includes the steps of: removing a part of the second layer along with a cutting line so that the layer removal region is formed, wherein a laser beam is irradiated on the first layer in the layer removal region without passing through the second layer; irradiating the laser beam on the first layer along with the cutting line so that a modified region is formed in the first layer; and separating a semiconductor element from the wafer by using a crack generated by the modified region.

In the above method, the laser beam is irradiated on the first layer without passing through the second layer. Specifically, in the layer removal region, no second layer exists. Here, the second layer causes reflection and/or scattering of the laser beam when the laser beam is entered into the first layer from the second layer side. Thus, the laser beam is irradiated on the first layer without reflection and scattering so that the modified region is formed at a preliminarily designed region in the first layer. Accordingly, the wafer can be separated, i.e., deiced with accuracy. Specifically, each semiconductor element can be separated with high yielding ratio and high quality.

Alternatively, the method may further includes the steps of: bonding a die-attach film having a plurality of film parts together with a dicing film on a backside of the first layer; and irradiating the laser beam on the first layer from the backside of the first layer through a clearance of the die-attach film so that the modified region is formed in the first layer. The layer removal region is a groove so that the second layer is divided by the groove. The die-attach film is disposed on the backside of the first layer, which is opposite to the second layer, so that each film part of the die-attach film contacts the backside of the first layer. The dicing film is disposed on the die-attach film so that the film parts of the die-attach film are bundled by the dicing film. The clearance of the die-attach film is formed between two neighboring film parts of the die-attach film. The clearance corresponds to the groove.

Further, a semiconductor wafer includes: a first layer having a first refraction index; a second layer having a second refraction index, which is different from the first refraction index; a top layer; a plurality of semiconductor elements disposed in the first layer, the second layer, and/or the top layer; and a layer removal region. The first layer, the second layer and the top layer are stacked in this order. The semiconductor elements are capable of being separated each other by irradiating a laser beam on the first layer along with a cutting line. The laser beam irradiation on the first layer provides a modified region in the first layer along with the cutting line so that the semiconductor elements are capable of being separated by a crack generated in the modified region. The layer removal region is provided in such a manner that the top layer in the layer removal region is removed from the wafer in order to irradiate the laser beam on the first layer in the layer removal region without passing through the top layer.

In the above wafer, the laser beam is irradiated on the first layer without passing through the top layer. Specifically, in the layer removal region, no top layer exists. Here, the top layer causes reflection and/or scattering of the laser beam when the laser beam is entered into the first layer from the second layer side. Thus, the laser beam is irradiated on the first layer without reflection and scattering so that the modified region is formed at a preliminarily designed region in the first layer. Accordingly, the wafer can be separated, i.e., deiced with accuracy. Specifically, each semiconductor element can be separated with high yielding ratio and high quality.

Alternatively, the layer removal region is filled with the second layer. Alternatively, the first layer is a silicon substrate, the second layer is an oxide layer, and the top layer is a SOI layer.

While the invention has been described with reference to preferred embodiments thereof, it is to be understood that the invention is not limited to the preferred embodiments and constructions. The invention is intended to cover various modification and equivalent arrangements. In addition, while the various combinations and configurations, which are preferred, other combinations and configurations, including more, less or only a single element, are also within the spirit and scope of the invention.

What is claimed is:

1. A semiconductor wafer comprising:
a first layer having a first refraction index;
a second layer having a second refraction index, which is different from the first refraction index;
a plurality of semiconductor elements disposed in the first and/or second layers; and
a layer removal region, wherein
the first layer and the second layer are stacked in this order,
the semiconductor elements are capable of being separated each other by irradiating a laser beam on the first layer along with a cutting line,
the laser beam irradiation on the first layer provides a modified region in the first layer along with the cutting line so that the semiconductor elements are capable of being separated by a crack generated in the modified region, and
the layer removal region is provided in such a manner that the second layer in the layer removal region is removed from the wafer in order to irradiate the laser beam on the first layer in the layer removal region without passing through the second layer.

2. The wafer according to claim 1, wherein
a difference between the first refraction index of the first layer and the second refraction index of the second layer, the first and the second layers which are adjacent each other, is the largest difference of a refraction index in the wafer.

3. The wafer according to claim 1, wherein
the layer removal region includes a whole area of the laser beam irradiation portion on the first layer.

4. The wafer according to claim 1, wherein
the layer removal region is disposed in a necessity minimum area for separating all semiconductor elements.

5. The wafer according to claim 1, wherein
the layer removal region is a groove so that the second layer is divided by the groove, and
the second layer facing the groove has a corner, which is tapered toward the first layer.

6. The wafer according to claim 1, wherein
the first layer includes a silicon substrate, and
the second layer includes a SOI layer and an oxide layer.

7. The wafer according to claim 1, further comprising:
a die-attach film having a plurality of film parts; and
a dicing film, wherein
the layer removal region is a groove so that the second layer is divided by the groove,
the die-attach film is disposed on a backside of the first layer, which is opposite to the second layer, so that each film part of the die-attach film contacts the backside of the first layer,
the dicing film is disposed on the die-attach film so that the film parts of the die-attach film are bundled by the dicing film,
the die-attach film further includes a clearance between two neighboring film parts of the die-attach film,
the clearance corresponds to the groove, and
the laser beam is capable of irradiating on the first layer from the backside of the first layer through the clearance so that the modified region is formed in the first layer.

8. A method for dicing a semiconductor wafer, which includes a first layer having a first refraction index, a second layer having a second refraction index, a plurality of semiconductor elements disposed in the first and/or second layers, and a layer removal region, wherein the first refraction index is different from the second refraction index, and wherein the first layer and the second layer are stacked in this order, the method comprising the steps of:
removing a part of the second layer along with a cutting line so that the layer removal region is formed, wherein a laser beam is irradiated on the first layer in the layer removal region without passing through the second layer;
irradiating the laser beam on the first layer along with the cutting line so that a modified region is formed in the first layer; and
separating a semiconductor element from the wafer by using a crack generated by the modified region.

9. The method according to claim 8, wherein
a difference between the first refraction index of the first layer and the second refraction index of the second layer, the first and the second layers which are adjacent each other, is the largest difference of a refraction index in the wafer.

10. The method according to claim 8, wherein
the layer removal region includes a whole area of the laser beam irradiation portion on the first layer.

11. The method according to claim 8, wherein
the layer removal region is disposed in a necessity minimum area for separating all semiconductor elements.

12. The method according to claim 8, wherein
the layer removal region is a groove so that the second layer is divided by the groove, and
the second layer facing the groove has a corner, which is tapered toward the first layer.

13. The method according to claim 8, wherein
the first layer includes a silicon substrate, and
the second layer includes a SOI layer and an oxide layer.

14. The method according to claim 8, further comprising the steps of:
bonding a die-attach film having a plurality of film parts together with a dicing film on a backside of the first layer; and
irradiating the laser beam on the first layer from the backside of the first layer through a clearance of the die-attach film so that the modified region is formed in the first layer, wherein
the layer removal region is a groove so that the second layer is divided by the groove,
the die-attach film is disposed on the backside of the first layer, which is opposite to the second layer, so that each film part of the die-attach film contacts the backside of the first layer,
the dicing film is disposed on the die-attach film so that the film parts of the die-attach film are bundled by the dicing film,
the clearance of the die-attach film is formed between two neighboring film parts of the die-attach film, and
the clearance corresponds to the groove.

15. A semiconductor wafer comprising:
a first layer having a first refraction index;
a second layer having a second refraction index, which is different from the first refraction index;
a top layer;
a plurality of semiconductor elements disposed in the first layer, the second layer, and/or the top layer; and
a layer removal region, wherein
the first layer, the second layer and the top layer are stacked in this order,
the semiconductor elements are capable of being separated each other by irradiating a laser beam on the first layer along with a cutting line,
the laser beam irradiation on the first layer provides a modified region in the first layer along with the cutting line so that the semiconductor elements are capable of being separated by a crack generated in the modified region,
the layer removal region is provided in such a manner that the top layer in the layer removal region is removed from the wafer in order to irradiate the laser beam on the first layer in the layer removal region without passing through the top layer.

16. The wafer according to claim 15, wherein
the layer removal region is filled with the second layer.

17. The wafer according to claim 15, wherein
the layer removal region is a groove so that the top layer is divided by the groove, and
the top layer facing the groove has a corner, which is tapered toward the first layer.

18. The wafer according to claim 15, wherein
the first layer is a silicon substrate,
the second layer is an oxide layer, and
the top layer is a SOI layer.

19. The wafer according to claim 15, further comprising:
a die-attach film having a plurality of film parts; and
a dicing film, wherein
the layer removal region is a groove so that the top layer is divided by the groove,
the die-attach film is disposed on a backside of the first layer, which is opposite to the top layer, so that each film part of the die-attach film contacts the backside of the first layer,
the dicing film is disposed on the die-attach film so that the film parts of the die-attach film are bundled by the dicing film,
the die-attach film further includes a clearance between two neighboring film parts of the die-attach film,
the clearance corresponds to the groove, and
the laser beam is capable of irradiating on the first layer from the backside of the first layer through the clearance so that the modified region is formed in the first layer.
